(19) United States
(12) Patent Application Publication
(10) Pub. No.: US 2007/0152206 A1
(43) Pub. Date: Jul. 5, 2007

(54) DEVICE FOR MANIPULATING PARTICLES USING DIELECTROPHORESIS EMPLOYING METAL-POST ELECTRODE STRUCTURE AND METHOD OF MANIPULATING PARTICLES USING THE DEVICE AT HIGH FLOW RATE

(75) Inventors: Yoon-kyoung CHO, Yongin-si, Gyeonggi-do (KR); Sung-young JEONG, Yongin-si, Gyeonggi-do (KR); Kak NAMKOONG, Yongin-si, Gyeonggi-do (KR); Chin-sung PARK, Yongin-si, Gyeonggi-do (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD., Suwon-si (KR)

(21) Appl. No.: 11/617,978

(22) Filed: Dec. 29, 2006

(30) Foreign Application Priority Data
Dec. 29, 2005 (KR) 10-2005-0133171

(51) Int. Cl. H01L 29/06

(52) U.S. Cl. 257/10

(57) ABSTRACT

A device and method for manipulating particles using dielectrophoresis are disclosed. The device comprises a chamber comprising an inlet port, an outlet port, and metal post electrodes, and a power supply, wherein the metal post electrodes are arranged in at least two rows in a vertical position with respect to the flow of fluids, each row comprises at least two metal post electrodes, each odd row is wired to a metal pad through a metal line, and each even row is wired to another metal pad through a metal line, and the power supply is connected to the metal pads.

This application claims priority to Korean Patent Application No. 10-2005-0133171, filed on Dec. 29, 2005, and all the benefits accruing therefrom under 35 U.S.C. §119, the disclosure of which is incorporated herein in its entirety by reference.

### BACKGROUND OF THE INVENTION

1. Field of the Invention

The present invention relates to a device for manipulating particles using dielectrophoresis, the device comprising a metal post electrode structure. The present invention further relates to a method of manipulating particles using the device at high flow rate.

2. Description of the Related Art

It is known that dielectrically polarizable particles, even if they are not electrically charged, are affected by a dielectrophoretic force when the effective polarizability of the particle is different from the polarizability of the medium around the particle. The movement of the particle through the medium is determined by dielectrcial properties (conductivity and permittivity). A dielectrophoretic force, which acts on a particle, can be represented as shown below:

$${F}_{DEP} = 2 π {a}^{3} {ɛ}_{m} Re ( \frac{{ɛ}_{p} - {ɛ}_{m}}{{ɛ}_{p} + 2 {ɛ}_{m}} ) ∇ {E}^{2} \qquad Equation 1$$

where F_{DEP}is a dielectrophoretic force, a is the radius of the particle, em is the permittivity of a medium around the particle, εₚ is the permittivity of the particle, Re is an operator denoting the real part of the complex number following the operator, E is the electric field, and ∇is the del vector operator. As shown in equation 1, the dielectrophoretic force is proportional to the volume of the particle, the permittivity difference between the medium and the particle, and the square of the electric field intensity.

The direction in which the particle is pulled can be represented as shown below:

$$f = [ \frac{{\tilde{σ}}_{p} - {\tilde{σ}}_{m}}{{\tilde{σ}}_{p} + 2 {\tilde{σ}}_{m}} ] \qquad Equation 2$$

where f is the Clausius-Mossotti (CM) factor, and \tilde{σ}ₚ and \tilde{σ}ₘ are the composite conductivity of the particle and the medium, respectively. When f>0, f_{DEP} is positive and the particle is pulled towards areas of high intensity in an electric field gradient. When f<0, f_{DEP}is negative and the particle is pulled towards areas of low intensity in an electric field gradient. As shown by equations 1 and 2, the dielectrophoretic force, which acts on the particle, can be changed according to the conductivity of the medium, and the frequency and amplitude of alternating voltages.

Research on separating and concentrating bacteria using dielectrophoresis has been conducted (Becker, F., et al., Proc. Natl. Acad. Sci. U S A. 1995, 92, 860-864; Chou, C.-F., et al., IEEE Eng. Med. Biol. Mag. 2003, 22, 62-67; Lapizco-Encinas, B. H., et al., Anal Chem. 2004a, 76, 1571-1579; Li, H.,Bashir, R. Sensors and Actuators B 2002, 86, 215-221; Prinz, C., et al., Lab Chip 2002, 2, 207-212; Huang, Y., et al., J. Anal. Chem. 2001, 73, 1549-1559; Yang, J et al., Biosens Bioelectron. 2002, 17, 605-618; Lapizco-Encinas, et al., Electrophoresis 2004b, 25, 1695-1704). In addition, a dielectrophoretic force has been used for selectively separating live bacteria and dead bacteria (Chou et al., 2003 and Lapizco-Encinas, et al., 2004a), and for separating different classes of bacteria (Huang, et al., 2001; and Lapizco-Encinas, et al., 2004b). However, conventional methods using dielectrophoresis employed very low flow rates. For example, bacterial separation has been performed in a static state ((Chou, et al. 2003; Li, H., et al. 2002) or with a flow velocity lower than 100 μm/sec (Becker, F. et al. 1995; Huang, Y. et al 2001). However, for fast and efficient concentration of liquid samples, there is a need to manipulate samples by dielectrophoresis employing a high flow rate, wherein particles can be collected in a solution efficiently.

Conventionally, with regard to concentrating and separating materials by dielectrophoresis, electrodes have been used having patterned surfaces. However, experiments have shown that the trap efficiency of bacteria falls below 20% at a flow velocity of 10 mm/sec or more.

To increase the trap efficiency of particles using dielectrophoresis, an octopole electrode structure has been used, wherein a dielectric cage is placed in the center of the fluid flow and cells can be collected at 50 μm/sec or lower flow rate (Muller, et al., Biosensors & Bioelectronics 1999, 14, 247-256).

Voldman and others have demonstrated a five-fold increase in the trapping capability of dielectrophoresis using an extruded quadrupole structure instead of using octopole electrodes, but particles could only be trapped and collected at a flow rate of 1.3 mm/sec or less. (Voldman, J., A Microfabricated Dielectrophoretic Trapping Array for Cell-based Biological Assays, doctoral dissertation, Massachusetts Institute of Technology, 2001)

Thus, a device and method to increase the concentration and separation efficiency of cells using dielectrophoresis is needed. In an attempt to increase the concentration and separation efficiency of cells, the inventors have found that an increased concentration rate could be achieved by dielectrophoresis at a flow rate greater than 1 mm/sec, or even at a flow rate greater than 10 mm/sec, when using an electrode post structure arranged in at least two rows in a vertical position with respect to the flow of fluids.

### BRIEF SUMMARY OF THE INVENTION

The present invention provides a device for manipulating particles at a high flow rate using dielectrophoresis.

In an embodiment, the device comprises a chamber comprising an inlet port, an outlet port, and metal post electrodes, wherein the metal post electrodes are arranged in at least two rows in a vertical position with respect to a flow of fluids, wherein each row comprises two or more metal post electrodes, wherein each odd row of the metal post electrodes is connected to a first metal pad through a metal line, and each even row of the metal post electrodes is connected to a second metal pad through a metal line; and a power supply which is connected to the metal pads.

The present invention also provides a method of manipulating particles at a high flow rate using the device.

In an embodiment, the method of manipulating particles comprises producing a spatially non-homogeneous electric field by applying an electric field to the metal post electrodes of the device, comprising a chamber comprising an inlet port, an outlet port, and metal post electrodes, wherein the metal post electrodes are arranged in at least two rows in a vertical position with respect to a flow of fluids, wherein each row comprises two or more metal post electrodes, wherein each odd row of the metal post electrodes is connected to a first metal pad through a metal line, and each even row of the metal post electrodes is connected to a second metal pad through a metal line; and a power supply which is connected to the metal pads, from the power supply; introducing a fluid comprising particles through the inlet port; and flowing the fluid through the chamber to the outlet port.

A method of manufacturing the device is also disclosed.

### BRIEF DESCRIPTION OF THE DRAWINGS

FIG. 1 is a schematic diagram showing an electrode structure including metal plates (FIGS. 1A and 1C), and an electrode structure including metal posts (FIGS. 1B and 1D).

FIG. 2 is a schematic diagram demonstrating a process of manufacturing rows of metal post electrodes used in a device for manipulating particles according to the invention.

FIGS. 3A and 3B are electron-microscopic images of metal posts manufactured on a glass substrate according to the process described in FIG. 2. FIGS. 3C and 3D are schematic diagrams demonstrating the dimensions of the metal posts shown in FIGS. 3A and 3B, respectively.

FIG. 4 is a schematic diagram showing an exploded view (FIG. 4A) and a perspective view (FIG. 4B) of a device for manipulating particles according to the invention.

FIG. 5 is a schematic diagram showing an embodiment of the electrode structure of the device shown in FIG. 4.

FIG. 6 is a schematic diagram further illustrating the device shown in FIG. 4. FIG. 6 illustrates the dimensions of the metal post arrangement within the device shown in FIG. 4.

FIG. 7 is a photographic image of the electrode structures used in the device shown in FIG. 4.

FIG. 8 is a schematic diagram showing a chamber of the device of FIG. 4.

FIG. 9 is a photographic image demonstrating the results when Escherichia coli (E. coli) cells are trapped for 2 minutes using dielectrophoresis. FIGS. 9A and 9C respectively show the control device containing metal plate electrodes and a side view of the control device illustrating the trapped cells. FIGS. 9B and 9D respectively show a device having Au-plated posts arranged on the bottom substrate and Au plates arranged on the top substrate and a side view of the device illustrating the trapped cells.

FIG. 10 is a graph showing the result of concentrating E. coli and Streptococcus mutans (S.M) using the control device for manipulating particles which includes the plane metal plate electrodes of FIG. 9A and 9C.

FIG. 11 is a graph showing the trapping efficiency of various dielectrophoretic devices as a function of electrode structure.

FIG. 12 is a graph showing the trapping efficiency using different flow rates using 2D and 3D+2D devices.

FIG. 13 shows graphs illustrating the the trapping efficiency and collecting efficiency, in percentage of collected cells and trapped cells, when the 3D+2D device is used to perform dielectrophoresis on different cell types and at different flow rates.

FIG. 14 a graph showing the concentration rate of bacterial cells when the same method used in FIG. 13 is employed.

### DETAILED DESCRIPTION OF THE INVENTION

The invention will now be described more fully with reference to the accompanying drawings, in which embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

In one embodiment, the invention provides a device for manipulating particles using dielectrophoresis. The device comprises a chamber comprising an inlet port, an outlet port, metal post electrodes, and a power supply, wherein the metal post electrodes are arranged in at least two rows in a vertical position with respect to the flow of fluids, wherein each row comprises two or more metal post electrodes, wherein each odd row of metal post electrodes is connected to a first metal pad through a metal line and each even row of metal post electrodes is connected to a second metal pad though a metal line; and a power supply connected to the metal pads.

In one embodiment, the metal posts in each odd row are arranged to place the metal posts between the corresponding metal posts in each even row.

In one embodiment, the metal posts in each odd row are connected to the metal pad through a single metal line, and the metal posts in each even row are connected to another metal pad through a single metal line. In one embodiment, the metal pads and the metal lines can be made of a material selected from gold (Au), copper (Cu), platinum (Pt), or any other conducting biocompatible metal. In another embodiment, the fluid-exposed surfaces of the metal pads and the metal lines can be made of a material selected from gold (Au), copper (Cu), platinum (Pt), or any other conducting biocompatible metal.

In one embodiment, the distance between each odd row and each even row is about 10 to about 100 μm, the distance between each metal post electrode in each row is about 10 to about 100 μm, and the height of the metal post electrodes is about 10 to about 100 μm, and preferably about 50 to about 100 μm.

In one embodiment, the metal posts are square cylinders or circular cylinders. However, the metal posts can have any shape.

In one embodiment, the outer surface of the metal posts form an angle of 50° to 120°, preferably 50° to 90° with the bottom surface of the metal posts. In this embodiment, the distance between the metal posts is less in the central area of the channel, where the flow rate is high, than the distance between the metal posts at the bottom surface. Accordingly, the metal posts have an inverted shape, wherein the cross section of the upper portion of the post is larger than that of the lower portion of the post, such posts form inverted square cylinders or inverted circular cylinders.

In another embodiment, the metal posts are made of a high-strength metal coated with Au. In an advantageous embodiment, the metal posts can be made by electroplating a high-strength metal post on a substrate, and then coating the high-strength metal post with Au using electroless plating. The high-strength metal can be nickel (Ni), nickel alloys, aluminum (Al), aluminum alloys, chromium (Cr), or chromium alloy deposits.

In one embodiment, the chamber is a microchamber having a bottom substrate and a top substrate, but the invention is not limited thereto. In another embodiment, the chamber is a microchannel. In another embodiment, the chamber can be made of a transparent substrate such as glass, silicon, pyrex, quartz, or SU-8.

In one embodiment, the chamber has a bottom substrate and a top substrate, and the metal post electrodes are arranged on the bottom substrate and on the top substrate. In one embodiment, the chamber can be made by first manufacturing the bottom substrate, manufacturing the top substrate, and then by bonding the two substrates together. Any bonding method known to one of ordinary skill in the art in the field of the invention can be used. The bonding method can include, for example, anodic bonding of a silicon substrate to a glass substrate, die bonding using an adhesive material which is made by a screen printing method, or bonding the substrates using an adhesive tape, such as 3M adhesive tape.

According to one embodiment of the invention, the rows of the metal posts on the bottom substrate are arranged to correspond to (align with) the rows of the metal posts on the top substrate. Furthermore, the metal posts in each odd row on the bottom substrate can be connected to the same metal pad to which the metal posts in each even row on the top substrate are connected, and vice versa.

In another embodiment, the chamber has a bottom substrate and a top substrate, wherein metal post electrodes are arranged on the bottom substrate, and metal plate electrodes are arranged on the top substrate.

The metal plate electrodes are arranged in rows, and each row is arranged in a vertical position with respect to the flow. Each row includes at least two metal plates. Each odd row is wired to a metal pad through a metal line, and each even row is wired to another metal pad through a metal line. In one embodiment, the rows of metal post electrodes on the bottom substrate correspond to the rows of metal plate electrodes on the top substrate; the metal post electrodes in each odd row on the bottom substrate and the metal plate electrodes in each even row on the top substrate can be wired to the same metal pad. Similarly, in this embodiment, the metal post electrodes in each even row on the bottom substrate and the metal plate electrodes in each odd row on the top substrate can also both be wired to a single metal pad.

In another embodiment, the device can optionally include components of conventional microfluidic devices, such as a pump, a valve for flowing fluids, and a detecting device, or a computer for automatically controlling the power supply.

In another embodiment, the device can be used to manipulate polarizable particles in samples using dielectrophoresis. The device can exhibit a strong power to trap and keep the particles, and thus is capable of manipulating the particles at a high flow rate of the samples through the device. When using the device to manipulate polarizable particles in samples using dielectrophoresis, the particles can be manipulated at a flow rate greater than 0.1 mm/sec, and preferably at a flow rate greater than 1 mm/sec. Examples of the samples used in an embodiment of the present invention include solutions containing particles which are biological materials, such as prokaryotic cells, eukaryotic cells, or viruses. Thus, particles, as used herein, can comprise prokaryotic cells, eukaryotic cells, viruses, cellular organelles, or any other polarizable biological material. Furthermore, the term “cells” means prokaryotic cells, eukaryotic cells, or both.

In another advantageous embodiment, the invention provides a method of manipulating particles using dielectrophoresis, The method comprises producing a spatially nonhomogeneous electric field by applying an electric field to the metal post electrodes of the device described above from the power supply; and introducing a fluid containing particles through the inlet port and flowing the fluid through the chamber to the outlet port. The method can further comprise trapping the particles in the spatially nonhomogeneous electric field; analyzing the trapped particles; or removing the electric field; and eluting the trapped particles through the outlet port.

With regard to the method of manipulating particles using dielectrophoresis, it is envisioned that the particles are, for example, prokaryotic cells, eukaryotic cells, viruses, or combinations comprising at least one of the foregoing. Samples containing cells or viruses that can be used in the method of manipulating particles using dielectrophoresis have a conductivity lower than 30 mS/m.

In one embodiment, the manipulating is concentrating the particles, but is not limited thereto. In one embodiment, the manipulating is separating cells or analyzing the trapped cells. For example, the trapped cells can be analyzed for cell viability, cell density, binding of ligands, etc. Optical methods, such as microscopy or detection of fluorescence, are examples of methods that can be used in analyzing properties of the trapped cells, but the methods are not limited thereto.

In one embodiment, the particles are cells or viruses, and the flow rate is greater than 0.1 mm/sec, greater than 1 mm/sec, and preferably greater than 1 mm/sec.

In one embodiment, the cells can be washed with buffer prior to eluting trapped cells from the dielectrophoresis device.

Hereinafter, a device for manipulating particles according to an embodiment of the present invention is explained more specifically with reference to the drawings.

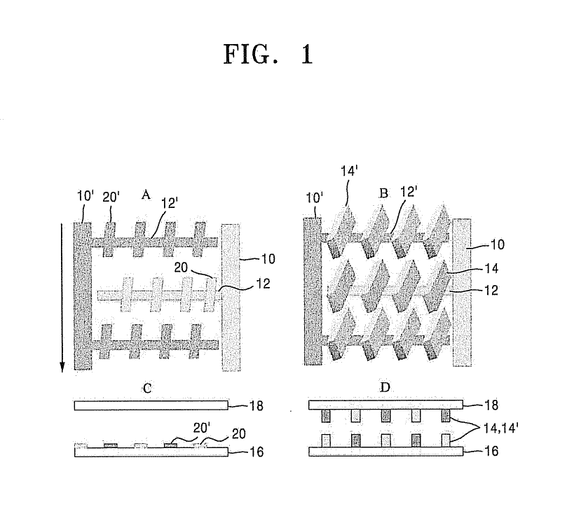

FIG. 1 is a schematic diagram showing various electrode structures. FIGS. 1A and 1C show an electrode structure including rows of metal plates (this structure is hereinafter referred to as a 2D structure). FIGS. 1B and 1D demonstrate an electrode structure according to the invention including arrays of metal posts (this structure is hereinafter referred to as a 3D structure.). FIGS. 1A and 1B are plan views, while FIGS. 1C and 1D are side views from the direction of the arrow in FIG. 1A.

In one device, demonstrated by FIG. 1A, rows of metal plates are arranged vertically to the flow direction of fluid, and each row includes a plurality of metal plates 20 and 20′. The metal plates 20′ in odd rows are wired to a metal pad 10′ through a metal line 12′, and the metal plates 20 in even rows are wired to another metal pad 10 through a metal line 12. As shown in FIG. 1C, a chamber includes a top substrate 18 and a bottom substrate 16, and the metal plates 20 and 20′ are arranged on the bottom substrate 16 of the chamber.

In an embodiment of the device of the invention, demonstrated by FIG. 1B, rows of metal posts 14 and 14′ are arranged vertically to the flow direction of the fluid, and each row includes four metal posts 14 and 14′. The metal posts 14′ in odd rows are wired to a metal pad 10′ through a metal line 12′, and the metal posts 14 in even rows are wired to another metal pad 10 through a metal line 12. As shown in the embodiment of FIG. 1D, the chamber includes a top substrate 18 and a bottom substrate 16, with the metal posts 14 and 14′ arranged on the bottom substrate 16 and the top substrate 18 of the chamber such that they are vertically aligned.

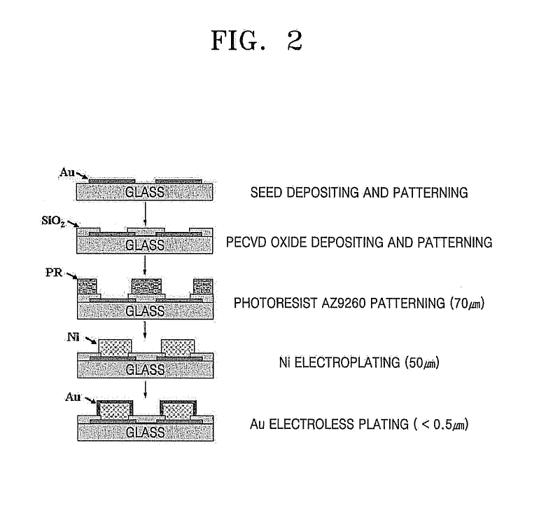

FIG. 2 is a schematic diagram showing an exemplary process of manufacturing rows of metal posts used in the device of the invention. In an initial step, titanium (Ti) and gold (Au) are sequentially deposited on a glass substrate and patterned. In FIG. 2, “Au” represents the deposited Ti and Au, with Au on the surface of the pattern. The patterned Ti and Au function as a metal line connecting the metal posts to a metal pad. Following the deposition and patterning of the Ti and Au layers, a SiO₂ layer is deposited using Plasma Enhanced Chemical Vapor Deposition (PECVD) and then patterned. The patterned SiO₂ layer functions as an insulating layer. Next, a photoresist is coated and patterned. Nickel is then deposited on the patterned region using electroplating to form nickel posts. Next, Au is plated on the nickel posts using electroless plating to yield the Au-plated nickel posts. The height of the nickel posts can be about 1 μm to about 100 μm, specifically about 50 μM to about 100 μm. In one embodiment, the height of the nickel post is about 50 μm. The Au-plated nickel posts have high strength, and thus do not break and can work as electrodes even at a rapid flow rate. In one embodiment, once the substrate having rows of metal posts is formed, it can be bonded with another substrate. The second substrate can have rows of metal posts, rows of metal plates, or neither. The technique used to bond the two substrates can be any technique known to one of ordinary skill in the art in the field. The bonding method can include, for example, anodic bonding of a silicon substrate to a glass substrate, die bonding using an adhesive material which is made by a screen printing method, or bonding the substrates using an adhesive tape such as 3M adhesive tape.

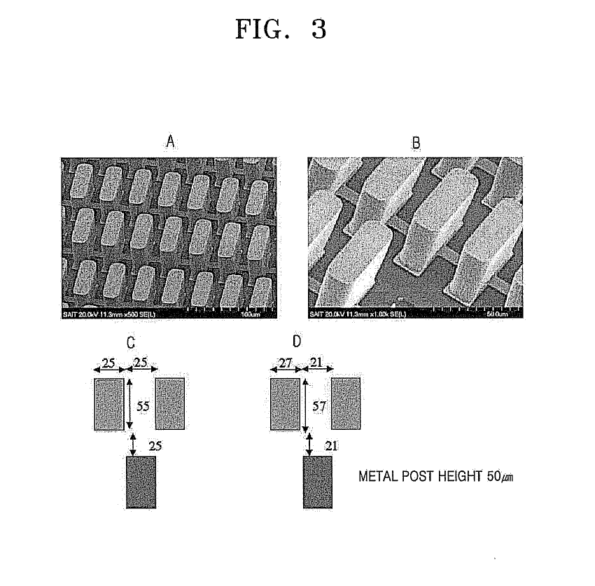

FIGS. 3A and 3B are electron-microscopic images showing metal posts manufactured on a glass substrate according to the process of described above and in FIG. 2. FIGS. 3C and 3D demonstrate the size of the metal posts shown in FIGS. 3A and 3B, respectively, wherein size is shown in micrometers. As shown in FIGS. 3A and 3B, each metal post is a rounded-square cylinder. The lower parts of the metal posts in each row are connected with each other through a metal line. FIGS. 3C and 3D show the arrangement and dimensions of the metal posts shown in FIGS. 3A and 3B, respectively. The height of metal posts manufactured according to one embodiment, as shown in FIG. 3, is 50 μm.

The present invention will be described in further detail with reference to the following examples. These examples are for illustrative purposes only, and should not be construed to limit the scope of the invention.

### EXAMPLES

Materials and Method

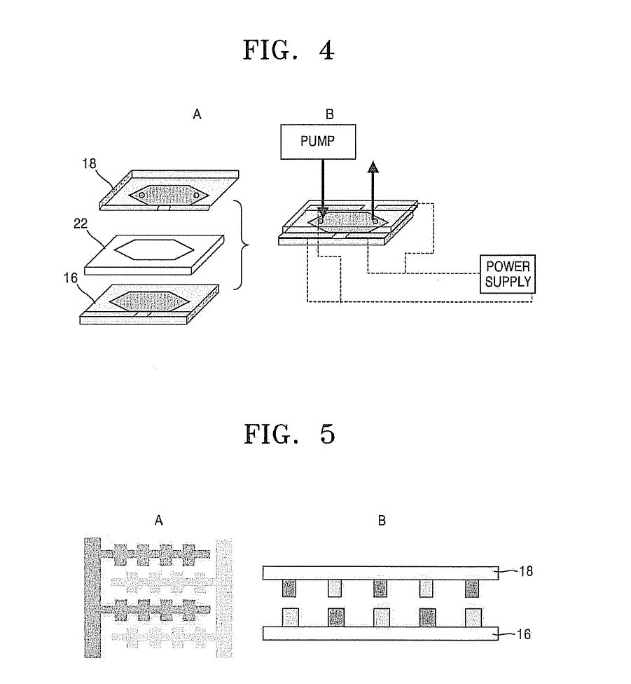

For the following examples, several kinds of microorganisms were concentrated using a device for manipulating particles according to the invention. FIG. 4A is a schematic diagram showing an exploded view and FIG. 4B is a schematic diagram showing a perspective view of a device for manipulating particles according to the invention. As shown in FIG. 4A, the device includes a top substrate 18 bonded to a bottom substrate 16 using a 3M adhesive tape (3M Corporation, US) 22, wherein rows of Au posts are arranged on both substrates 18 and 16 prior to bonding. FIG. 4B shows the device of FIG. 4A connected to a power supply via metal pads. A pump is used to make a fluid flow into the device via an inlet port and flow out of the device via an outlet port.

FIG. 5 is a schematic diagram showing the structure of the electrodes of the device shown in FIG. 4. FIG. 5A is a plan view of the device, wherein each of four rows of Au-plated posts is connected to an Au pad through an Au line, and each row of the Au-plated posts includes four Au-plated posts. Here, odd rows of the Au-plated posts are connected to a single Au pad and even rows of the Au-plated posts are connected to another Au pad. FIG. 5B is a side view diagram of the chamber showing that the Au-plated posts are arranged on both the top substrate 18 and the bottom substrate 16. FIGS. 5A and 5B are simplified diagrams of the device used in the following examples of the invention. The device which was actually used in the following examples had 60 rows of Au-plated posts, and each row had 120 Au-plated posts.

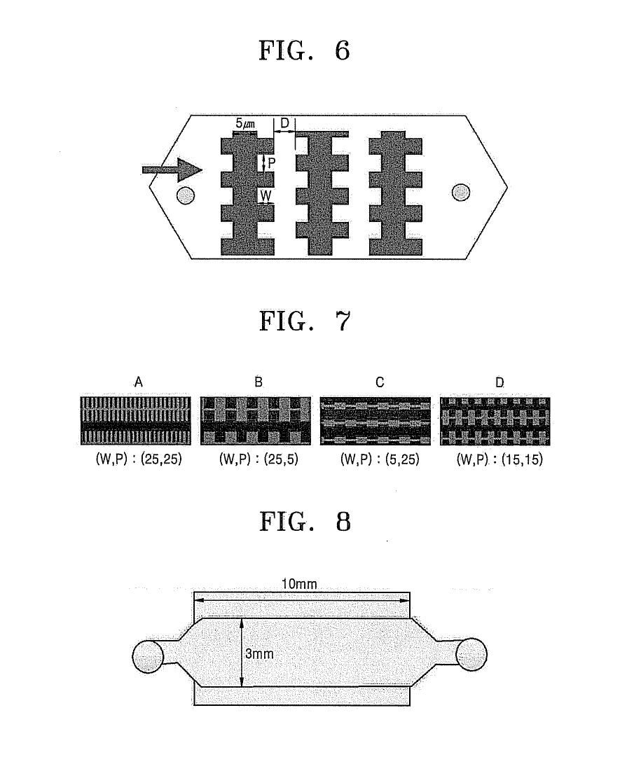

FIG. 6 is a schematic diagram further illustrating the device of FIG. 4. In particular, FIG. 6 illustrates the dimensions and arrangement of the metal posts of the device of FIG. 4. The width of a Au line, which connects Au-plated posts to a metal pad, is about 5 μm, the distance between Au-plated posts in a row is P (pitch), the width of a protruding part of a metal post from a metal line is W (width), and the distance between rows of Au-plated posts is D. The arrow indicates the fluid flow direction.

FIG. 7 presents a photographic image of several electrode structures used in the device of FIG. 4. Devices having the electrode structures represented by FIGS. 7A through 7D showed similar results. Therefore, for convenience, only the results using the electrode structure of shown in FIG. 7A are disclosed in the following example.

FIG. 8 is a schematic diagram showing the chamber of the device of FIG. 4. The chamber has a length of 10 mm, a width of 3 mm, and a height of 90 μm. The volume of the chamber is about 3.5 μm.

The height of the Au-plated posts is 50 μm.

For the following example, the device used as a control device contained the same electrode structure as the post electrode structure of FIG. 7A, except that the electrodes were Au plates (height 100 nm) that were arranged only on the bottom substrate, and not on the top substrate.

In the example, a device according to the invention having an electrode structure wherein Au-plated plates were arranged on the top substrate 18 and Au-plated posts were arranged on the bottom substrate 16 (this structure is referred to as a 2D+3D structure) was also used. The 2D+3D structure device has the same electrode structure as shown in FIG. 7A except that Au-plated plates are arranged on the top substrate 18 and Au-plated posts are arranged on the bottom substrate 16.

### Example 1

### Concentration of a Solution Containing Microorganisms

In this example, two types of Gram-negative bacteria, E. coli (ATCC #11775) and Pseudomonas fluorescence (ATCC #13525), and two types of Gram-positive bacteria, Streptococcus mutans (ATCC #35668) and Staphylococcus epidermidis (ATCC #14990), were used. E. coli (ATCC #11775) and Pseudomonas fluorescence (ATCC #13525) were cultured in a brain heart infusion (BHI) broth (BD, US) at 37° C., and Streptococcus mutans (ATCC #35668) and Staphylococcus epidermidis (ATCC #14990) were cultured in a nutrition broth (DB, US) at 27° C. and 37° C. during the night. The cultures were centrifuged at 5000 rpm for 5 min at 4° C., and washed three times with 0.1 M of sodium phosphate buffer. The conductivity was set by diluting the cultures with distilled water.

In order to fill the bacteria-concentrating dielectrophoresis device and remove bubbles in chips, phosphate buffered saline (PBS) (2 mS/m) was flowed through the device. Bubbles were removed by flowing at a rate of 5000 μl/min for about 30 sec. Power was turned on to supply an electric field (for example, 20 V, 100 kHz). The cell solution to be concentrated (for example, E. coli 10⁶ cell/ml, conductivity 2 mS/m) was pumped into the device at a fixed flow rate (for example, 250 μl/min) for a specified time (for example, 1 min).

To verify whether the device was trapping bacterial cells, the device was observed through a microscope. When the process was observed through a microscope, it was observed that bacteria were being trapped in the vicinity of the electrodes in the region of greater electric field gradient strength around the electrodes.

Unlabeled bacteria were used in the experiments to assess the trapping efficiency and the collecting ratio. The trapping efficiency, the elution efficiency, the collecting efficiency, and the concentration rate are calculated by the following equations:
Trapping efficiency (%)=(inflow bacteria number−outflow bacteria number)/(inflow bacteria number)×100
Elution efficiency (%)=(eluted bacteria number)/(inflow bacteria number−outflow bacteria number)×100
Collecting efficiency (%)=(eluted bacteria number)/(inflow bacteria number)×100
Concentration rate (fold)=(eluted bacteria concentration)/(inflow bacteria concentration),
wherein the inflow bacteria number is the number of cells in solution which flowed into the device, the outflow bacteria number is the number of bacteria which were not trapped by the dielectrophoresis phenomenon and flowed out of the device, and the eluted bacteria number is the number of bacteria from among the trapped bacteria in the device which were eluted from the device when the electric field was removed. For example, when 500 μl of 10⁶ cell/ml solution was added to the device and flowed through the device for 2 min at a flow rate of 250 μl/min with an electric field applied, the concentration of the solution which flowed out was 2×10⁵ cell/ml, the input bacteria number was 5×10⁵ cells, the outflow bacteria number was 10⁵ cells, and the trapping efficiency was 4×10⁵ cell/5×10⁵ cell×100%=80%. When 10 μm of buffer was subsequently added to the device and flowed through the device with no electric field applied, the concentration of the eluted solution was 3.6×10⁷ cell/ml and the eluted bacteria number was 3.6×10⁵ cells. Accordingly, the elution efficiency was 3.6×10⁵ cell/4×10⁵ cell×100%=90% and the collecting efficiency was 3.6×10⁵ cell/5×10⁵ cell×100, that is, 72%. Therefore, the concentration rate was 3.6×10⁷ cell/ml/10⁶ cell/ml, that is, 36-fold, and the maximum concentration rate possible was 50-fold because 500 μl of sample was flowed into the device and only 10 μl was eluted.

Two methods were used to measure the concentration of cells: a colony count method was used when determining the concentration of a sample having less than than 10⁶ cell/ml and a fluorescence labeling method using a BACLIGHT™ Bacterial viability kit (Molecular probes, US) was used when determining the concentration of a sample having greater than 10⁶ cell/ml. Fluorescence labeling was performed by adding 3 μl of a dye mixture of SYTO 9 and propidium iodide to 1ml of the cell solution. After 20 min. passed, fluorescence intensity was measured using a SPECTRAMAX® Gemini XS. A relative quantitation value was measured by first obtaining a standard curve through serial-dilution of bacteria solution of which the OD₆₀₀ value was 1, and then comparing the concentration of the cell solution to be measured to the standard curve. The absolute number of bacteria in the bacteria solution of which the OD₆₀₀=1 was measured by a colony count method by diluting the bacteria solution.

When quantification analysis was not necessary, the bacteria were labeled as either alive or dead using the BACLIGHT® Bacterial viability kit (Molecular probes, US). In such an analysis, the bacteria solution was pumped into the device, used as a concentration chip, to which an electric field was applied, and bacteria trapped between the electrodes of the device were observed using a fluorescence microscope.

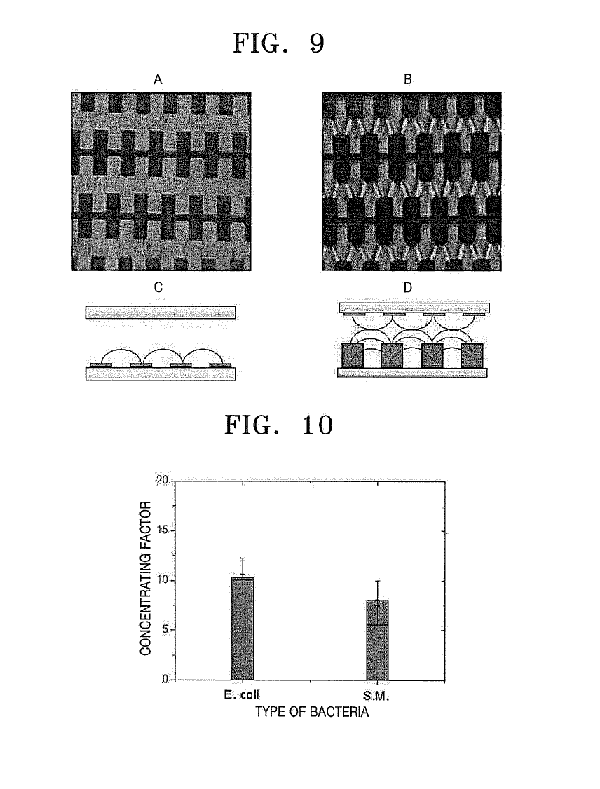

FIG. 9 shows results of cell trapping by dielectrophoresis where 10⁷ cells/ml (2 mS/m) of E. coli in sodium phosphate buffer was pumped into the device at 250 μl/min of flow rate for 2 min cells. FIGS. 9A and 9C respectively show fluorescence results for the control device and a side view the control device illustrating the trapped cells (2D device). FIGS. 9B and 9D respectively show fluorescence results for a device according to the invention having Au-plated posts arranged on the bottom substrate and Au-plated plates arranged on the top substrate and a side view of the device illustrating the trapped cells (2D+3D device). The voltage and frequency used in the experiment were 20V and 300 kHz, respectively. The results of testing dielectrophoretic properties of four types of bacteria showed that the trap efficiency of all of four types of bacteria was excellent at 300 kHz in 2 mS/m conductivity solution.

FIG. 10 is a graph showing the result of concentrating E. coli (E. coli) and Streptococcus mutans (S.M) obtained using the dielectrophoresis device having the Au-plated plate electrode structure of FIG. 9A and 9C (the 2D device). 0.1 OD₆₀₀ of E. coli (1×10⁷ cells/ml) and Streptococcus mutans (S.M) (6×10⁷ cells/ml), at a conductivity adjusted to 0.5 mS/m, were each flowed into the dielectrophoresis device of FIG. 9A through the inlet port for 1 minute at a flow rate of 500 μl/min, while an electric field of 20 V and 300 kHz was applied in order to trap the cells using (+) DEP. Then, trapped cells were washed with PBS (2 mS/m). Subsequently, 10 μl of the same buffer were flowed into the device with no applied electric field in order to collect the cells.

FIG. 10 is a graph showing the results of concentrating E. coli and Streptococcus mutans (S.M) using the dielectrophoresis device (the 2D device) of FIG. 9A. The concentration efficiency for concentrating E. coli and Streptococcus mutans (S.M) using the dielectrophoresis device of FIG. 9A averaged less than 10-fold. The trapping efficiency, elution efficiency, collecting efficiency, and concentration efficiency, for cells concentrated using the 2D device (control) and the 3D+2D device in this experiment experiment, are shown in Table 1 below.

TABLE 1

| | 2D | 3D + 2D |
|---|---|---|
| | (250 μl/min) | (250 μl/min) |
| | (21.4 mm/sec) | (21.4 mm/sec) |
| Concentration rate (fold) | E. coli ≦10 fold | E. coli ≦22.8 fold |
| (maximum 50 fold for the | S.M. ≦7 fold | S.E. ≦19.4 fold |
| case of 100% collected) | | |
| Collecting efficiency (%) | E. coli ≦19% | E. coli ≦45.6% |
| | S.M. ≦13% | S.E. ≦38.8% |
| Concentration time (min) | ≦2 min | ≦2 min |
| Trapping efficiency (%) | E. coli ≦33% | E. coli ≦73.7% |
| | S.M. ≦30% | S.E. ≦46. 12% |
| Elution efficiency (%) | E. coli ≦59% | E. coli ≦62.0% |
| | S.M. ≦45% | S.E. ≦85.8% |

where E. coli is Escherichia coli, S.M. is Streptococcus mutans, and S.E. is Staphylococcus epidermidis.

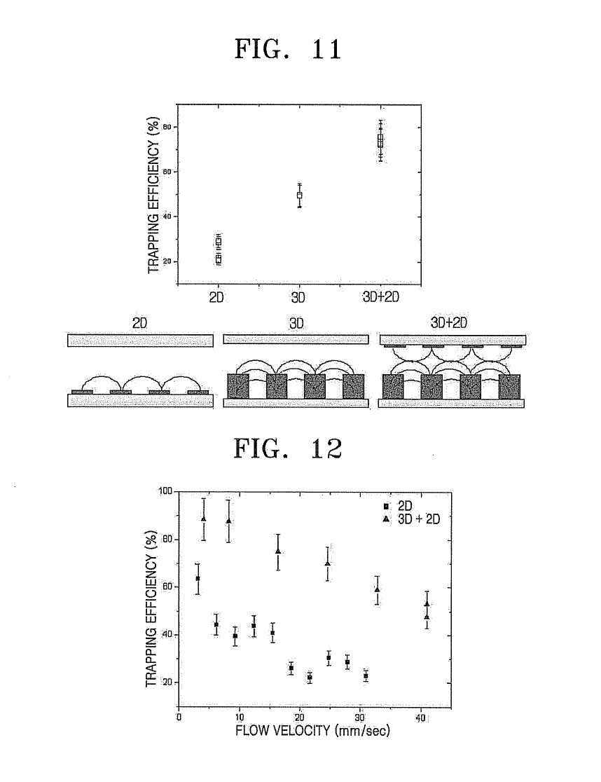

FIG. 11 presents a graph showing the trapping efficiency as a function of the electrode structures for each device described. In FIG. 11, 2D, 3D, and 3D+2D represent dielectrophoresis devices having an electrode structure where Au-plated plates are arranged only on the bottom substrate, a structure where Au-plated post electrode are arranged only on the bottom substrate, and a structure where Au-plated post electrodes are arranged on the bottom substrate with Au-plated plates arranged on the top substrate, respectively. As shown in FIG. 11, the trapping efficiency was higher for the devices having Au-plated post electrode structure, as compared to the devices having an Au-plated plate electrode structure. Among the devices having Au-plated post electrode structures, the 3D+2D device showed higher trapping efficiency than the 3D device. With reference to FIG. 11, the experiments to collect cells using dielectrophoresis were performed by flowing 10⁷ cells/ml (2 mS/m) of E. coli in sodium phosphate buffer at a flow rate of 250 μl/min (15.5 mm/sec) for 2 minutes while applying 20 Vp-p, 300 kHz of electric field.

FIG. 12 is a graph showing the trapping efficiency of trapped cells in the 2D and 3D+2D devices described for FIG. 11 when flow rate was varied. The experiment was performed in the same manner as the experiment in FIG. 11 except that the flow rate was changed. As shown in FIG. 12, the 3D+2D device showed higher trapping efficiency than the 2D device.

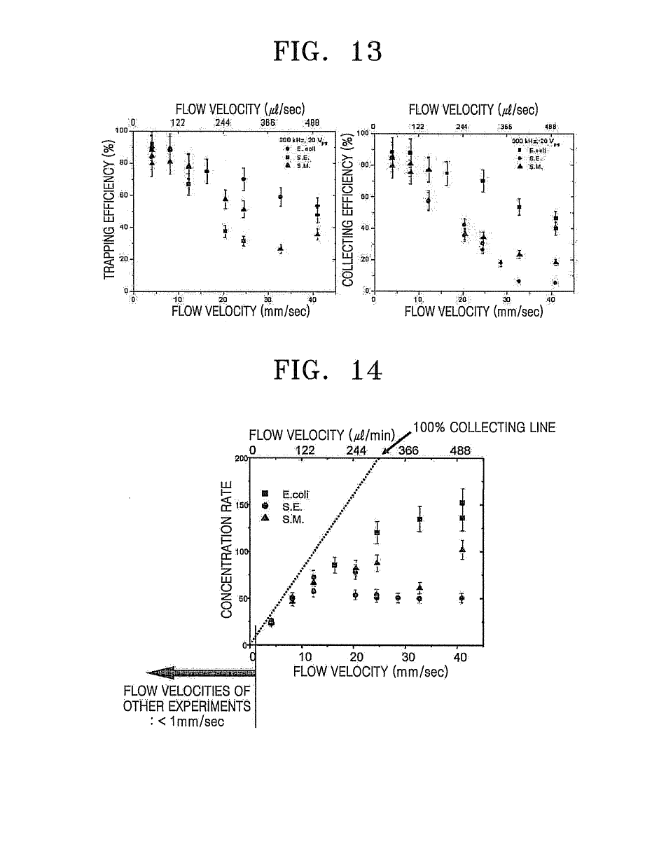

FIG. 13 presents graphs showing the trapping efficiency and the collecting efficiency of cells collected from the trapped cells by dielectrophoresis using the 3D+2D device when the type of cells and the flow rate were varied. 10⁷ cells/ml of E. coli, 10⁷ cells/ml of Streptococcus mutans (ATCC #35668) (S.M.), and 10⁷ cells/ml of Staphylococcus epidermidis (ATCC #14990) (S.E.) (conductivity of each was 2 mS/m) in sodium phosphate buffer were flowed through the 3D+2D device at a flow rate of 250 μ/min (15.5 mm/sec) for 2 minutes, while 20Vp-p, 300 kHz of electric field was applied. The cells were washed using washing solution (PBS, 2 mS/m), and then collected from the device by flowing an elution solution through the device in the absence of an applied electric field. The trapping efficiency and collecting efficiency were determined by measuring the concentration after dyeing the collected cells with a dye. The results are summarized in Table 1 above.

FIG. 14 is a graph showing the concentration efficiency of bacteria under the same conditions as in the experiments shown in FIG. 13. As shown in FIG. 14, the concentration efficiency was as high as 50- to 150-fold. This concentration efficiency is clearly superior to the result obtained using the 2D device as shown in FIG. 10 where the concentration rate was I10fold or less. The concentration efficiency in FIG. 14 was determined by dividing the concentration of collected bacteria, which were collected for 2 minutes, by the input (or influx) concentration.

In summary, the invention provides a device comprising an electrode structure including arranged metal posts, such that, when an electric field is applied to the electrode, particles can be collected with a strong collecting force, and thus the particles can be manipulated at high flow rate.

The terminology used herein is for the purpose of describing particular embodiments only and is not intended to be limiting of the invention. The terms “a” and “an” do not denote a limitation of quantity, but rather denote the presence of at least one of the referenced item. The term “or” means “and/or”. The terms “comprising”, “having”, “including”, and “containing” are to be construed as open-ended terms (i.e., meaning “including, but not limited to”).

Recitation of ranges of values are merely intended to serve as a shorthand method of referring individually to each separate value falling within the range, unless otherwise indicated herein, and each separate value is incorporated into the specification as if it were individually recited herein. The endpoints of all ranges are included within the range and independently combinable.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein. Unless defined otherwise, technical and scientific terms used herein have the same meaning as is commonly understood by one of skill in the art to which this invention belongs.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context. While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A device for manipulating particles using dielectrophoresis, comprising:
a chamber comprising an inlet port, an outlet port, and metal post electrodes,
wherein the metal post electrodes are arranged in at least two rows in a vertical position with respect to a flow of fluids,
wherein each row comprises two or more metal post electrodes,
wherein each odd row of the metal post electrodes is connected to a first metal pad through a metal line, and each even row of the metal post electrodes is connected to a second metal pad through a metal line; and
a power supply which is connected to the metal pads.

2. The device of claim 1, wherein the metal post electrodes in each odd row are placed between the metal post electrodes in each even row.

3. The device of claim 1, wherein the metal post electrodes in one odd row are connected to the first metal pad through a single metal line, and the metal post electrodes in one even row are connected to the second metal pad through a single metal line.

4. The device of claim 1, wherein
a distance between the metal post electrodes in the odd row and the metal post electrodes in the even row is about 10 μm to about 100 μm,
a distance between the metal post electrodes in each row is about 10 μm to about 100 μm, and
a height of the metal post electrodes is about 1 to about 100 μm.

5. The device of claim 1, wherein the metal post electrodes are square cylinders or circular cylinders.

6. The device of claim 1, wherein an outer surface of the metal post electrodes make an angle with a bottom surface to which the metal post electrodes are attached of about 50° to about 120°.

7. The device of claim 1, wherein the metal post electrodes comprise a high-strength metal coated with Au.

8. The device of claim 1, wherein the material of the metal post electrodes is selected from the group consisting of nickel, a nickel alloy, aluminum, an aluminum alloys, chromium, and a chromium alloy.

9. The device of claim 1, wherein the chamber is a microchamber comprising a bottom substrate and a top substrate.

10. The device of claim 1, wherein the chamber further comprises a bottom substrate and a top substrate, and the metal post electrodes are arranged on each of the bottom substrate and the top substrate.

11. The device of claim 10, wherein the rows of metal post electrodes on the bottom substrate are arranged to correspond to the rows of metal post electrodes on the top substrate, and
the metal post electrodes in each odd row on the bottom substrate and the metal post electrodes on each even row in the top substrate are connected to the same metal pad, and the metal post electrodes on each even row in the bottom substrate and the metal post electrodes on each odd row in the top substrate are connected to the same metal pad.

12. The device of claim 1, wherein the chamber further comprises a bottom substrate and a top substrate,
wherein metal post electrodes are arranged on the bottom substrate and metal plate electrodes are arranged on the top substrate;
wherein the metal plate electrodes are arranged in at least two rows which are in a vertical position with respect to the flow of fluid and each row comprises two or more metal plate electrodes; and
wherein each odd row of metal plate electrodes is connected to a third metal pad through a metal line, and each even row of metal plate electrodes is connected to a fourth metal pad through a metal line.

13. The device of claim 12, wherein the rows of metal post electrodes on the bottom substrate are arranged to correspond to the rows of metals plate electrodes on the top substrate, and
wherein the first metal pad and the fourth metal pad are the same metal pad and the second metal pad and the third metal pad are the same metal pad.

14. A method of manipulating particles, the method comprising:
producing a spatially nonhomogeneous electric field by applying an electric field to the metal post electrodes of the device of claim 1 from the power supply;
introducing a fluid comprising particles through the inlet port; and
flowing the fluid through the chamber to the outlet port.

15. The method of claim 14, wherein the particles comprise biological materials.

16. The method of claim 15, wherein the biological materials comprise prokaryotic cells, eukaryotic cells, or viruses.

17. The method of claim 14, wherein flowing the fluid comprises
trapping the particles in the spatially nonhomogeneous electric field.

18. The method of claim 17, further comprising:
removing the electric field; and
eluting the trapped particles through the outlet port.

19. The method of claim 17, further comprising
analyzing the trapped particles using an optical method of detection.

20. The method of claim 14, wherein the particles are biological materials comprising prokaryotic cells, eukaryotic cells, or viruses, and the flow rate is 1 mm/sec or higher.

21. A method of manufacturing a substrate with metal post electrodes for a device for manipulating particles, the method comprising:
patterning a substrate with metal lines comprising a surface of gold;
depositing an insulating layer on the substrate and patterning the insulating layer such that the metal lines are exposed;
depositing and patterning a photoresist such that the metal lines are exposed;
forming metal posts on the metal lines; and
depositing a conducting metal on the metal posts to obtain metal post electrodes, wherein each metal post electrode comprises a height of about 1 to about 100 μm, and wherein a distance between two metal post electrodes on a metal line is about 10 μm to about 100 μm and a distance between metal post electrodes on two adjacent metal lines is about 10 μm to about 100 μm.

22. The method of claim 21, further comprising
connecting a first metal line to a first metal pad;
connecting a second metal line to a second metal pad, wherein the second metal line is adjacent to the first metal line on the substrate;
bonding the substrate with the metal post electrodes to a second substrate; and
connecting a power supply to the metal pads.
